(19) United States
(12) Patent Application Publication
(10) Pub. No.: US 2002/0147955 A1
(43) Pub. Date: Oct. 10, 2002

(54) Internal storage memory with EDAC protection

(76) Inventors: Robert W. James, Albuquerque, NM (US); Arthur H. Waldie, Albuquerque, NM (US); Timothy John Canales, Albuquerque, NM (US)

Correspondence Address: CALFEE HALTER & GRISWOLD, LLP, 800 SUPERIOR AVENUE, SUITE 1400, CLEVELAND, OH, 44114, US

(21) Appl. No.: 09/829,103

(22) Filed: Apr. 9, 2001

Related U.S. Application Data
(60) Provisional application No. 60/203,209, filed on May 11, 2000.

(51) Int. Cl. H03M 13/00

(52) U.S. Cl. 714/758

(57) ABSTRACT

An internal memory section of a digital processing system protectable by error detection and correction (EDAC) codes comprises at least one bank of registers for storing digital words and EDAC codes corresponding thereto. An EDAC code is generated for each digital word stored in a register of the at least one bank and the stored digital words of the at least one bank are checked with their EDAC codes. Also disclosed is a method of accessing digital words protectable by EDAC codes in a digital processing system which comprises the steps of: storing digital words and EDAC codes corresponding thereto in at least one bank of registers of an internal memory of the system; generating an EDAC code for each digital word upon storage; reading digital words and their corresponding EDAC codes from designated registers of the at least one bank; and checking the read digital words with their EDAC codes.

This application claims priority from U.S. Provisional Application Serial No. 60/203,209 filed May 11, 2000.

### BACKGROUND OF THE INVENTION

The present invention is directed to internal storage memory of a processing system, in general, and more particularly, to internal storage memory having error detection and correction protection.

Internal storage memory of a processing system is conventionally considered memory relatively small in size compared to a main memory of the system, disposed in close proximity to the central processing unit (CPU) and other bus units, like a memory management unit (MMU) and direct memory access (DMA) controller, for example, and generally fabricated on the same integrated circuit (IC) as the CPU and other bus master units. The most common of the internal memory systems is the cache memory which may store anywhere from as small as 4K bytes of digital words with the upper limit usually set by considerations to IC manufacturing yield and fabrication costs .

Normally, the memory cells of a cache memory are of a relatively simple circuit structure and because of size restrictions, are not multiple voted for protection. Current systems use a parity bit for checking errors in storage and transmission of cached words within the processing system. Parity bit checking is appropriate for most working environments. But, in radiation environments, especially on-board spacecraft and high flying aircraft where there is very little or substantially less atmosphere to absorb the radiation particles, upsets in the memory storage due to radiation particles are frequent and may become a problem if the only protection is a parity bit check.

Parity bit checking techniques generally permits the detection, but not correction, of an upset in a stored digital word of the internal memory. Upon detection, the parity scheme permits a de-validation of the digital word and forces a re-read of the word in error from external main memory. These re-reads cause delays in execution of instructions by the processing system and if they become frequent will lead to a substantial deterioration in performance of the system. In addition, if an even number of bits are upset in a common digital word, the parity scheme can not detect the multiple errors. The occurrence of multiple errors in a common digital word is considered somewhat rare working outside of a radiation or more severe environment, but the risk of such occurrences increase as the frequency of upsets increase such as in the more severe radiation environments.

Accordingly, for internal storage memory operating in radiation environments, some additional form of protection against errors caused by upsets is desirable. The present invention overcomes the drawbacks of the current systems and provide such additional protection against frequent upsets in internal memory storage cells caused by more severe operating environments.

### SUMMARY OF THE INVENTION

In accordance with one aspect of the present invention, an internal memory section of a digital processing system protectable by error detection and correction (EDAC) codes comprises: at least one bank of registers for storing digital words and EDAC codes corresponding thereto; means for generating an EDAC code for each digital word stored in a register of said at least one bank; and means for checking the stored digital words of said at least one bank with their EDAC codes.

In accordance with another aspect of the present invention, a method of accessing digital words protectable by error detection and correction (EDAC) codes in a digital processing system comprises the steps of: storing digital words and EDAC codes corresponding thereto in at least one bank of registers of an internal memory of said system; generating an EDAC code for each digital word upon storage; reading digital words and their corresponding EDAC codes from designated registers of the at least one bank; and checking said read digital words with their EDAC codes.

### BRIEF DESCRIPTION OF THE DRAWINGS

FIG. 1 is a block diagram schematic of a conventional internal cache memory for describing a background for the present invention.

FIG. 2 is a block diagram schematic of an internal memory suitable for embodying the principles of the present invention.

FIG. 3 is a block diagram schematic of an alternate embodiment of the present invention.

### DETAILED DESCRIPTION OF THE INVENTION

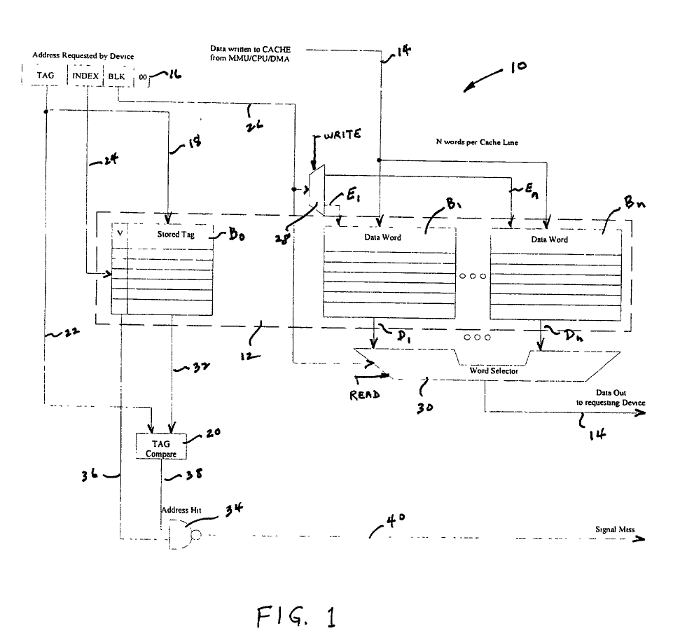

FIG. 1 is a block diagram schematic of a conventional internal cache memory 10 of a digital processing system. Digital words may be written into and read from the cache memory 10 by any one of the bus units (not shown), like the CPU, DMA controller or MMU, for example, which are generally disposed on the same integrated circuit (IC) in close proximity to the internal memory 10. A core storage portion 12 of the cache memory 10 is shown within dashed lines and includes a number of banks of registers or memory cells B₀ through Bₙ, where n for the present embodiment is five. In each register in the banks B₁ through Bₙ may be stored a digital word of m bits in length, m for the present embodiment is 32 bits, for example. Memory cells having the address of the four banks comprise a line of digital words of the cache memory. In corresponding memory cells of the same address in bank B₀ is stored an identification word or tag of the line of words. Along with each tag is included a validation code V which may be stored in a separate individual memory of its own or stored in bank B₀ along with each tag. In the present embodiment, the validation code is one bit.

A digital word may be presented over a data bus 14 from any one of the bus master units to be written into a line in a selected one of the banks of registers. An address for the digital word is presented to an address register 16. The address includes the fields of a tag of the digital word which is supplied to the bank B₀ over a tag bus 18 and also to a compare circuit 20 over signal lines 22, an index which is supplied to the cache memory core 12 over an address bus 24 to access a designated line of words in the cache storage core 12, and a block field (blk) which is supplied to inputs of a demultiplexer circuit 28 and a word selector circuit 30 over signal lines 26 to identify a designated word in the accessed line of words. Enable signals E₁ through Eₙ are output from the demultiplexer 28 and supplied to each of the banks B₁ through Bₙ, respectively. Digital words read from the banks B₁ through Bₙ are supplied to inputs of the word selector 30 over lines D₁ through Dₙ, respectively. A digital word selected by and output form the word selector 30 is presented over the data bus 14 to the requesting device. A tag word accessed from bank B₀ is input to the compare circuit 20 over signal lines 32 and an associated validation bit is input to a NAND logic gate 34 over a signal line 36. A compare signal output from circuit 20 is provided to another input of logic gate 34 over a signal line 38. Write and read commands issued over the processor bus may be coupled to enable inputs of the circuits 28 and 30, respectively, for the selection thereof.

In operation, if a digital word is to be written into a bank of registers of the core 12, then the word is presented over the data bus 14 by the requesting bus master unit and its address stored in the register 16. The index field of the address accesses the proper line in the banks of registers and the blk field is demultiplexed by the circuit 28 to enable the proper bank of registers. Upon issuance of the write command, the tag on bus 18 and the digital word on the data bus 14 are written into the corresponding addressed registers. If a digital word is to be read from a bank of registers, the address thereof is again stored in the register 16. As in the write operation, the index field of the address accesses the proper line in the banks of registers and the blk field is provided to the circuit 30 to select a word from the words D₁ through Dₙ of the accessed line. The tag accessed by the address from bank B₀ is compared with the tag of the immediate address stored in the register 16 using compare circuit 20. If there is a match, an address hit signal is output over signal line 38. Concurrently, the status of the associated validation bit V is output over signal line 36. If the validation bit is set and there is an address hit, the logic gate 34 generates a signal over a signal line 40 indicative of the presence of the designated tag in the bank B₀ which permits a read operation to occur. Upon issuance of the read command, the designated word accessed from the core 12 through word selector 30 is output over the data bus 40 for the requesting bus unit to read. The operations of the various circuits of cache memory 10 are governed synchronously by a clock signal (not shown). The read and write operations may take one or more clock cycles to be performed.

Present cache or internal memories use parity bits to provide protection against upsets, but this is considered inadequate in severe radiation and thin atmosphere environments due to the potential of increased frequency of such upsets. Accordingly, the present invention which will be described herein below in connection with one or more embodiments is intended to provide improved protection, especially in high radiation environments.

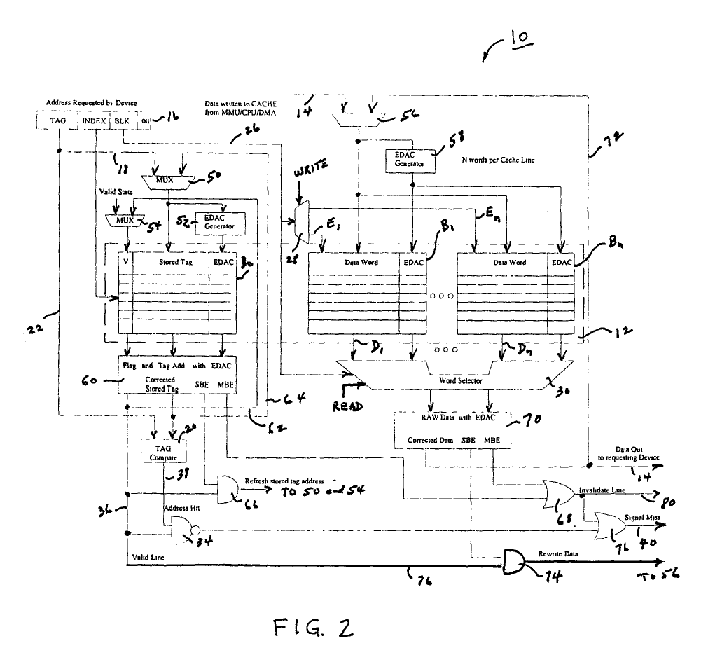

FIG. 2 depicts an embodiment of an enhanced cache memory 10 for describing one aspect of the present invention. Common elements with the conventional embodiment of FIG. 1 will be referred to with the same reference numerals for convenience. Moreover the connections of the circuitry which remain in common between the embodiments will not be redescribed for the sake of brevity. In connection with this aspect of the present embodiment, error detection and correction (EDAC) codes are added to each of the words stored in the banks of registers B₀ through Bₙ . Accordingly, the size of the registers in the banks will be increased in length or number of bits to accommodate the additional bits of the EDAC codes which for the present embodiment comprise 8 bits each. Also added to the conventional embodiment is circuitry for the generation and checking of the EDAC codes for each word as it is written into and read from its designated register.

Referring to FIG. 2, the tag from the address register 16 is input to one input of a multiplexer circuit 50 over the signal lines 18 and the output of the multiplexer 50 is coupled to the tag word input of the register bank B₀ The address tag is also coupled to an input of an EDAC code generator circuit 52 and the output thereof is coupled to the EDAC code input of the memory bank B₀. A valid bit associated with the address tag is input to one input of another multiplexer 54 and the output thereof is coupled to a valid bit input of the bank B₀. Moreover the data bus 14 is coupled to one input of a multiplexer circuit 56 and the output thereof is coupled to the digital word input of each of the banks B₁ through Bₙ and also to an EDAC code generator 58. The output of generator 58 is coupled to an EDAC code input of each of the banks B₁ through Bₙ.

Still further, the V bit, the tag and corresponding EDAC code of the selected line of bank B₀ is input to an EDAC code checking circuit 60. Output from circuit 60 are a conditioned V bit which is coupled to one input of the NAND logic gate 34 over signal line 36 and also coupled to another input of multiplexer 54 over signal line 62; a corrected tag code which is coupled to one input of the compare circuit 20 and also coupled to another input of the multiplexer 50 over signal line 64; a single bit error (SBE) indication signal which is input of an AND logic gate 66 along with the conditioned V bit; and a multiple bit error (MBE) indication signal which is coupled to an input of an OR logic gate 68. The output of the logic gate 66 is coupled to select inputs of the multiplexers 50 and 54. The conditioned V bit indicates a non-valid re-load output back to the tag memory whenever the V bit output from memory B₀ is not valid or a multiple bit error in the tag code or digital word as will become more apparent from the description below. The storage of the V bit shown included in the tag memory bank B₀ is usually fabricated either in special memory cells the are substantially less susceptible to upsets or in protected memory cells that may be all synchronously cleared allowing for fast cache “flush” type operations.

Yet further, the selected word and its EDAC code output from the word selector 30 are input to another EDAC code checking circuit 70. Output from the circuit 70 are a corrected digital word which is coupled over the bus 14 and also to another input of the multiplexer 56 over signal line 72; a single bit error (SBE) indication signal which is input to an AND logic gate 74 along with the corrected V bit over line 76; and a multiple bit error (MBE) indication signal which is coupled to another input of the OR gate 68. The output of the AND gate 74 is coupled to a select input of the multiplexer 56. The output of the OR gate 68 is input to an OR logic gate 76 along with the output of NAND gate 34. OR gate 68 also effects an invalidate signal over a signal line 80.

For a write operation, a data word is presented over the bus 14 and the corresponding address therefor is stored in the register 16. The tag of the address is selected by the multiplexer 50 and a corresponding V bit is selected by the multiplexer 54. Both are stored in the register of bank B₀ accessed by the index code of the address. In addition, the data word is selected by the multiplexer 56 and applied to the inputs of the registers of the banks and stored in the register accessed by the blk code of the address. In each case, an EDAC code is generated, for the selected tag by EDAC code generator 52 and for the selected data word by EDAC code generator 58 and the generated EDAC codes are applied to the inputs of their respective banks and stored in their respective accessed registers.

For a read operation, an address is presented to and stored in the register 16. The contents of the register of bank B₀ accessed by the index code of the address is operated on by the checking circuit 60. Likewise, the contents of the accessed register of the selected bank B₁ through Bₙ is operated on by the checking circuit 70. In each circuit 60 and 70, the digital word input thereto is analyzed according to an EDAC code algorithm to generate an EDAC code of the digital word which is compared with the EDAC code accessed form the designated register also input to the checking circuit. If the generated and stored EDAC codes match, then neither of the signals SBE or MBE is set and the digital word output over the data bus 14 may be accepted as in the conventional system provided the tag and validation bit are proper. If a signal miss signal is generated over signal line 40, the data word is not accepted by the requesting unit and will be read from the main memory or other external memory section.

However, if a single bit error is identified in the tag code, a corrected tag code ( and validation code under some conditions) is generated and the SBE indication signal is set. If the AND gate 66 determines that the SBE is set and the corresponding V bit is set, then it causes a refresh of the stored tag code with the corrected tag code and its corresponding generated EDAC code via generator 52. This is accomplished in the present embodiment by selecting the corrected tag code with the multiplexer 50 and the correct V bit with the multiplexer 54 and writing them along with the newly generated EDAC code into the register designated by the immediate address. In this condition, the corrected tag is compared with the tag of the address in circuit 20.

Now, if a single bit error is identified in an accessed digital word, circuit 70 will generate a corrected digital word which is output over bus 14 and input to multiplexer 56, and an SBE indication signal which causes a rewrite of the corrected digital word into the register designated by the immediate address provided that the corresponding V bit is set. This is accomplished in the present embodiment by selecting the corrected digital word in the multiplexer 56 for storage in the designated register along with its newly generated EDAC code via generator 58. Note that when a single bit error is detected, in one or both of the circuits 60 and 70, it means that the stored EDAC code did not match the generated code. Accordingly, the error could be in the word or in the associated EDAC code. Therefor, a rewrite of the corrected word is accompanied by a rewrite of a newly generated EDAC code therefor.

Still further, if a multiple bit error (i.e. two or more bits in error) is detected in either the tag code or digital word by circuit 60 and/or 70, an invalidate signal is generated over line 80 by the logic gate 68. In addition, a miss signal is also generated over line 40 (this signal is also generated if the V bit is not set). If either the invalidate signal or signal miss signal is generated, the data word on the bus 14 is not accepted and the processor will read the data word in from the main memory or some other external memory section. The EDAC codes contemplated for use in the present embodiment can detect most multiple bit errors or upsets including even multiple bit errors, some of which not being detectable by a parity bit.

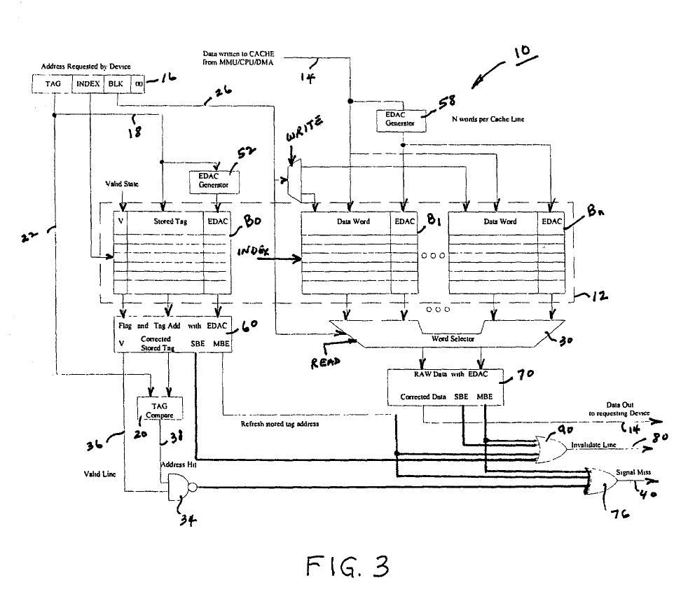

An alternate embodiment of the present invention is shown in the block diagram schematic of FIG. 3. In the embodiment of FIG. 3, the multiplexer circuits of the embodiment of FIG. 2 for rewriting the words and corresponding EDAC codes into the designated registers have been eliminated. And the logic handling SBEs and MBEs is changed. In this alternate embodiment, the SBE and MBE indication signals from the circuits 60 and 70 are input to an OR logic gate 90 which effects the invalidate signal over line 80. In addition, the MBE signals from the circuits 60 and 70 are input to the OR gate 76 in place of the invalidate signal of line 80. All logic controlling rewrite or refresh is eliminated. If either of the SBE or MBE signals of either circuit 60 or circuit 70 is set, the invalidate signal is generated over signal line 80 which causes a logical zero to be written to the V bit of the tag of the current address. Under this condition, the tag is devalidated at the next clock cycle. Alternatively, if only one of the SBE signals is set, then the invalidate signal may not be set and the corrected data word output over the bus 14 may be accepted by the requesting device. If either of the MBE signals is set, the signal miss signal will be generated and the corrected data will not be accepted.

While the present invention is described above in connection with one or more specific embodiments, it is understood that no limitations on the present invention should be implied by such embodiments. Rather, the present invention should be construed in breadth and broad scope in accordance with the recitation of the appended claims.

We claim:

1. An internal memory section of a digital processing system protectable by error detection and correction (EDAC) codes, said internal memory comprising:
at least one bank of registers for storing digital words and EDAC codes corresponding thereto;
means for generating an EDAC code for each digital word stored in a register of said at least one bank; and
means for checking the stored digital words of said at least one bank with their EDAC codes.

2. The memory section of claim 1 including means for reading digital words from designated registers of the at least one bank; and wherein the checking means is operative to check each digital word read from its designated register against its corresponding stored EDAC code, and to correct said digital word if it detects a single bit error therein.

3. The memory section of claim 2 including means for restoring the corrected digital word into its designated register in response to the detection of a single bit error in the checked digital word.

4. The memory section of claim 2 wherein the checking means is further operative to generate a single bit error signal if it detects a single bit error in said checked digital word, and to generate a multiple bit error signal if it detects a multiple bit error in said checked digital word.

5. The memory section of claim 4 including means responsive to the multiple bit error signal for generating a signal to invalidate the read digital word.

6. The memory section of claim 4 including means responsive to the single bit error signal or the multiple bit error signal for generating a signal to invalidate the read digital word.

7. The memory section of claim 4 including means responsive to the multiple bit error signal for generating a signal indicative of a signal miss.

8. The memory section of claim 1 including a bank of registers for storing both tag codes respectively associated with the stored digital words, and EDAC codes corresponding thereto.

9. The memory section of claim 8 wherein the digital word registers and tag code registers have common addresses.

10. The memory section of claim 8 including:
a second means for generating an EDAC code for each stored tag code; and
a second means for checking the stored tag codes with their EDAC codes.

11. The memory section of claim 10 including means for reading tag codes and their EDAC codes from designated registers; wherein the second checking means is operative to check each tag code read from its designated register against its corresponding EDAC code, and to generate a corrected tag code if a single bit error is detected in said checked tag code.

12. The memory section of claim 11 including means for restoring the corrected tag code to its designated register in response to the detection of a single bit error in the checked tag code.

13. The memory section of claim 12 wherein each tag code includes a valid code; and wherein the restoring means includes means for restoring the valid code as part of the corrected tag code.

14. The memory section of claim 11 wherein the second checking means is further operative to generate a second single bit error signal if it detects a single bit error in said checked tag code, and to generate a second multiple bit error signal if it detects a multiple bit error in said checked tag code.

15. The memory section of claim 14 including means for reading digital words from designated registers of the at least one bank; and means responsive to the second multiple bit error signal for generating a signal to invalidate the read digital word.

16. The memory section of claim 14 including means for reading digital words from designated registers of the at least one bank; and means responsive to the second single bit error signal or the second multiple bit error signal for generating a signal to invalidate the read digital word.

17. The memory section of claim 14 including means responsive to the second multiple bit error signal for generating a signal indicative of a signal miss.

18. The memory section of claim 1 wherein the memory section comprises a cache memory.

19. A method of accessing digital words protectable by error detection and correction (EDAC) codes in a digital processing system, said method comprising the steps of:
storing digital words and EDAC codes corresponding thereto in at least one bank of registers of an internal memory of said system;
generating an EDAC code for each digital word upon storage;
reading digital words and their corresponding EDAC codes from designated registers of the at least one bank; and
checking said read digital words with their EDAC codes.

20. The method of claim 19 including the steps of: checking each digital word read from its designated register against its corresponding stored EDAC code, and correcting said digital word if a single bit error is detected therein by said checking step.

21. The method of claim 20 including restoring the corrected digital word into its designated register in response to the detection of a single bit error in the checked digital word.

22. The method of claim 20 including generating a single bit error signal if a single bit error is detected in said checked digital word; and generating a multiple bit error signal if a multiple bit error is detected in said checked digital word.

23. The method of claim 22 including generating a signal to invalidate the read digital word in response to the generated multiple bit error signal.

24. The method of claim 22 including generating a signal to invalidate the read digital word in response to the generated single bit error signal or the generated multiple bit error signal.

25. The method of claim 22 including generating a signal indicative of a signal miss in response to the generated multiple bit error signal.

26. The method of claim 19 including storing in a bank of registers both tag codes respectively associated with the stored digital words, and EDAC codes corresponding thereto.

27. The method of claim 26 including the steps of:
generating an EDAC code for each tag code upon the storage thereof;
reading tag codes and their EDAC codes from designated registers of; and
checking the read tag codes with their EDAC codes.

28. The method of claim 27 including the steps of: checking each tag code read from its designated register against its corresponding EDAC code; and generating a corrected tag code if a single bit error is detected in said checked tag code.

29. The method of claim 28 including restoring the corrected tag code to its designated register in response to the detection of a single bit error in the checked tag code.

30. The method claim 29 including restoring a valid code as part of the corrected tag code.

31. The method of claim 28 including the steps of: generating a second single bit error signal if a single bit error is detected in said checked tag code; and generating a second multiple bit error signal if a multiple bit error is detected in said checked tag code.

32. The method of claim 31 including generating a signal to invalidate the read digital word in response to the generated second multiple bit error signal.

33. The method claim 31 including generating a signal to invalidate the read digital word in response to the generated second single bit error signal or the generated second multiple bit error signal.

34. The method of claim 31 including generating a signal indicative of a signal miss in response to the generated second multiple bit error signal.
